(19) United States
(12) Patent Application Publication
(10) Pub. No.: US 2026/0351935 A1
(43) Pub. Date: Nov. 5, 2026

(54) ELECTRICAL JUNCTION BOX

(71) Applicant: Sumitomo Wiring Systems, Ltd., Yokkaichi-shi, Mie (JP)

(72) Inventors: Masanao KURITA, Yokkaichi-shi, Mie (JP); Maiko ISSHIKI, Yokkaichi-shi, Mie (JP)

(73) Assignee: Sumitomo Wiring Systems, Ltd., Yokkaichi-shi, Mie (JP)

(21) Appl. No.: 19/491,554

(22) PCT Filed: Jun. 12, 2024
(86) PCT No.: PCT/JP2024/021376

§ 371 Date: Dec. 9, 2025

(30) Foreign Application Priority Data
Jun. 15, 2023 (JP) 2023-098666

(51) Int. Cl. H02G 3/08

(52) U.S. Cl. CPC H02G 3/081

(57) ABSTRACT

An electrical junction box includes a case made of a resin material and electric circuit components accommodated and held in the case, and the electric circuit components includes a contactor that generates a magnetic field and an electric current sensor. The electrical junction box includes a metal plate interposed between the contactor and the electric current sensor. The case includes cover portions that cover main surfaces of the metal plate inside the case.

### CROSS-REFERENCE TO RELATED APPLICATIONS

This application is the U.S. national stage of PCT/JP2024/021376 filed on Jun. 12, 2024, which claims priority of Japanese Patent Application No. JP 2023-098666 filed on Jun. 15, 2023, the contents of which are incorporated herein.

### TECHNICAL FIELD

The present disclosure relates to an electrical junction box.

### BACKGROUND

Conventionally, some electrical junction boxes are provided, for example, in a battery pack of a vehicle (for example, see JP 2013-16467A). The battery pack includes a battery pack case, an electrical junction box, and a plurality of battery cells.

The electrical junction box includes a case made of a resin material, and electric circuit components accommodated and held in the case. The electric circuit components include a contactor that is a type of relay, an electric current sensor, a bus bar, and the like. The electric circuit components monitor the current values, the temperatures, and the like of the battery cells, thereby realizing optimum input/output of the battery pack.

Incidentally, the above contactor has a coil portion therein, and thus generates a magnetic field when operating. If the electric current sensor is affected by the magnetic field, the detection accuracy decreases. This is a major problem particularly when decreasing the size of the electrical junction box. In view of this, for example, it is conceivable that a metal plate that partitions the contactor and the electric current sensor is provided inside the case. However, when disposing the metal plate inside the case, there is a risk that the metal plate will come into contact with another electrical component. Specifically, for example, there is a risk that the bus bar will be electrically connected to the metal plate. In addition, there is a risk that, for example, a flexible coated electric wire will be damaged by rubbing against an edge or the like of the metal plate.

An object of the present disclosure is to provide an electrical junction box that can suppress a decrease in the detection accuracy of an electric current sensor while preventing an electric circuit component and a metal plate from coming into contact with each other.

### SUMMARY

An electrical junction box according to the present disclosure including: a case made of a resin material; electric circuit components configured to be accommodated and held in the case, the electric circuit components including an electric current sensor and a magnetic field generating component configured to generate a magnetic field; and a metal plate interposed between the magnetic field generating component and the electric current sensor, wherein the case includes cover portions covering main surfaces of the metal plate inside the case.

### Advantageous Effects

With the electrical junction box according to the present disclosure, it is possible to suppress a decrease in the detection accuracy of an electric current sensor while preventing an electric circuit component and a metal plate from coming into contact with each other.

### BRIEF DESCRIPTION OF DRAWINGS

FIG. 1 is an exploded perspective view of an electrical junction box according to an embodiment of the present disclosure.

FIG. 2 is a plan view of a lower case and electric circuit components according to the embodiment.

FIG. 3 is a perspective view of the lower case and the electric circuit components according to the embodiment.

FIG. 4 is a partial cross-sectional view of the electrical junction box according to the embodiment.

FIG. 5 is a cross-sectional view taken along the line 5-5 in FIG. 4.

### DETAILED DESCRIPTION OF PREFERRED EMBODIMENTS

First, an embodiment of the present disclosure will be listed and described.

In a first aspect, an electrical junction box according to the present disclosure includes:
a case made of a resin material; electric circuit components configured to be accommodated and held in the case, the electric circuit components including an electric current sensor and a magnetic-field generating component configured to generate a magnetic field; and a metal plate interposed between the magnetic field generating component and the electric current sensor,
wherein the case includes cover portions covering main surfaces of the metal plate inside the case.

With this configuration, since the electrical junction box includes the metal plate interposed between the magnetic field generating component and the electric current sensor, it is possible to keep the electric current sensor from being affected by a magnetic field generated by magnetic field generating component. Thus, it is possible to suppress a decrease in the detection accuracy of the electric current sensor. In addition, since the case includes the cover portions that cover the main surfaces of the metal plate inside the case, the metal plate is prevented from coming into direct contact with another electric circuit component. Thus, for example, the bus bar that connects the magnetic-field generating component and the electric current sensor is prevented from being electrically connected to the metal plate. In addition, for example, a flexible coated electric wire is prevented from being damaged by rubbing against an edge or the like of the metal plate.

In a second aspect according to the first aspect, the case may include: an insertion opening through which the metal plate is insertable between the cover portions from the outside; and an accommodating bottom portion that links the cover portions to each other at a leading end portion in an insertion direction of the metal plate.

With this configuration, since the case includes the insertion opening through which the metal plate is insertable between the cover portions from the outside, and the accommodating bottom portion that links the cover portions to each other at the leading end portion in the insertion direction of the metal plate, the metal plate can be easily disposed by inserting it from the insertion opening.

In a third aspect according to the first or the second aspect, the electric circuit components may include a bus bar that connects the magnetic-field generating component and the electric current sensor, and the bus bar is disposed such that a main surface of the bus bar faces a bottom surface inside the case.

With this configuration, the bus bar that connects the magnetic field generating component and the electric current sensor is disposed such that the main surface of the bus bar faces the bottom surface inside the case, and thus the metal plate can be easily interposed between the magnetic field generating component and the electric current sensor. That is, for example, in a configuration in which the bus bar is disposed such that the main surface of the bus bar is orthogonal to the bottom surface of the case, it is difficult to interpose the metal plate between the magnetic field generating component and the electric current sensor due to interference of the bus bar, but that can be avoided.

In a fourth aspect according to any one of the first to the third aspects, the metal plate may include a plurality of different flat surface portions disposed around the electric current sensor or the magnetic field generating component.

With this configuration, since the metal plate includes a plurality of different flat surface portions disposed around the electric current sensor or the magnetic field generating component, it is possible to orderly partition the magnetic field generating component and the electric current sensor compared with a case where a metal plate consisting of a single metal plate is used.

In a fifth aspect, according to the fourth aspect, the metal plate may include a bent portion that links the plurality of different flat surface portions.

With this configuration, since the metal plate includes a bent portion that links the plurality of different flat surface portions, for example, the number of components can be reduced, compared with a case where a plurality of different flat surface portions are independent separate members.

In a sixth aspect according to any one of the first to the fifth aspects, the metal plate may be disposed in such a manner as to shield all of a surface of the electric current sensor that faces the magnetic field generating component and a surface of the magnetic field generating component that faces the electric current sensor.

With this configuration, since the metal plate is disposed in such a manner as to shield all of a surface of the electric current sensor that faces the magnetic field generating component and a surface of the magnetic-field generating component that faces the electric current sensor, the electric current sensor can be further kept from being affected by a magnetic field compared with a configuration where some of the surfaces are not shielded. Thus, it is possible to further suppress a decrease in the detection accuracy of the electric current sensor.

A specific example of the electrical junction box according to the present disclosure will be described below with reference to the drawings. In the drawings, parts of the configurations may be shown in an exaggerated or simplified manner for convenience of description. In addition, dimensional ratios of portions may be different between figures. “Parallel”, “orthogonal”, and “perfectly circular” in the present specification include not only being exactly parallel, orthogonal, and perfectly circular but also approximately parallel, orthogonal, and perfectly circular within a range in which the operation and effects of the present embodiment can be achieved. Note that, the present disclosure is not limited to these examples, but rather is indicated by the claims, and is intended to include all modifications that are within the meanings and the scope that are equivalent to those of the claims.

### Configuration of Electrical Junction Box 11

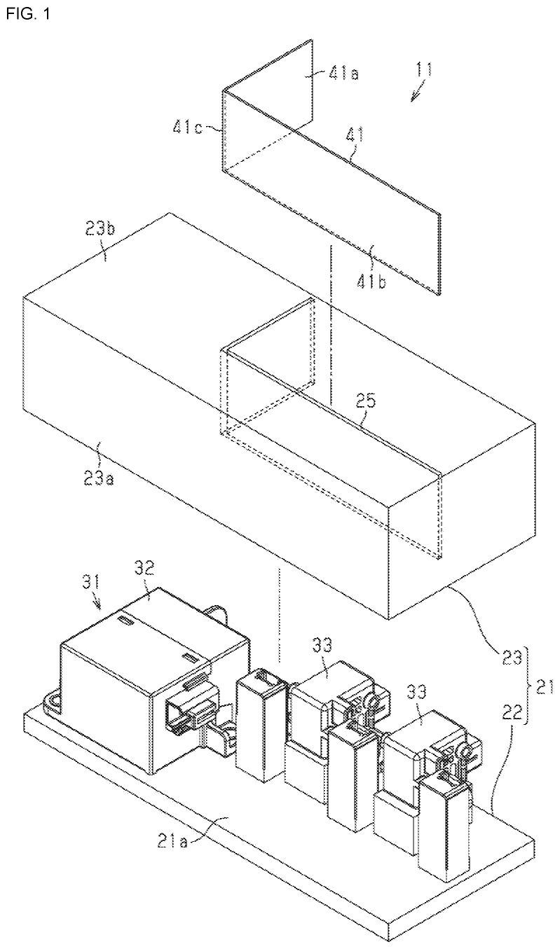

As shown in FIG. 1, an electrical junction box 11 includes a case 21, electric circuit components 31, and a metal plate 41. The electrical junction box 11 according to the present embodiment is provided in a battery pack mounted in a vehicle such as an electric automobile. That is, the electrical junction box 11 is accommodated in a battery pack case together with a plurality of battery cells.

### Configuration of Case 21

The case 21 includes a lower case 22 and an upper case 23. The lower case 22 and the upper case 23 are formed of a resin material. The lower case 22 is formed in a rectangular flat plate shape. The upper case 23 is configured to be attachable to the upper side of the lower case 22. The upper case 23 includes a side wall portion 23a in the form of a rectangular tube corresponding to a peripheral edge of the lower case 22, and an upper wall portion 23b that closes an upper end of the side wall portion 23a.

### Configuration of Electric Circuit Component 31

The electric circuit components 31 are accommodated and held in the case 21 while being disposed on the upper surface of the lower case 22 that is a bottom surface 21a inside the case 21.

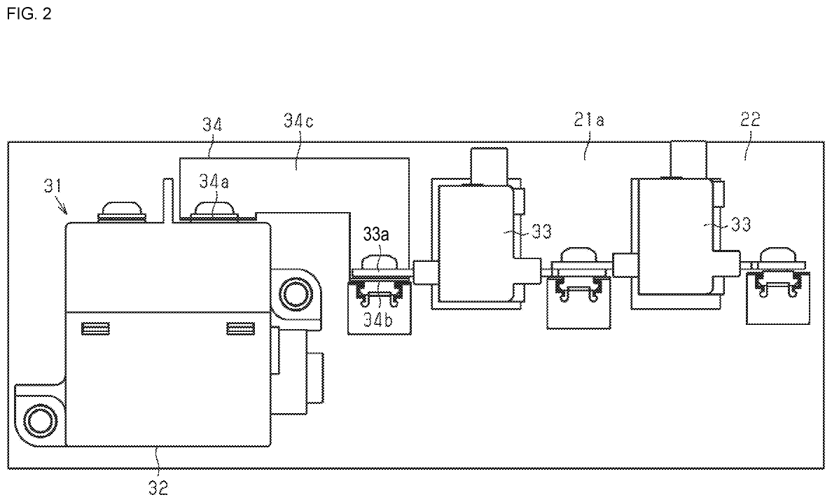

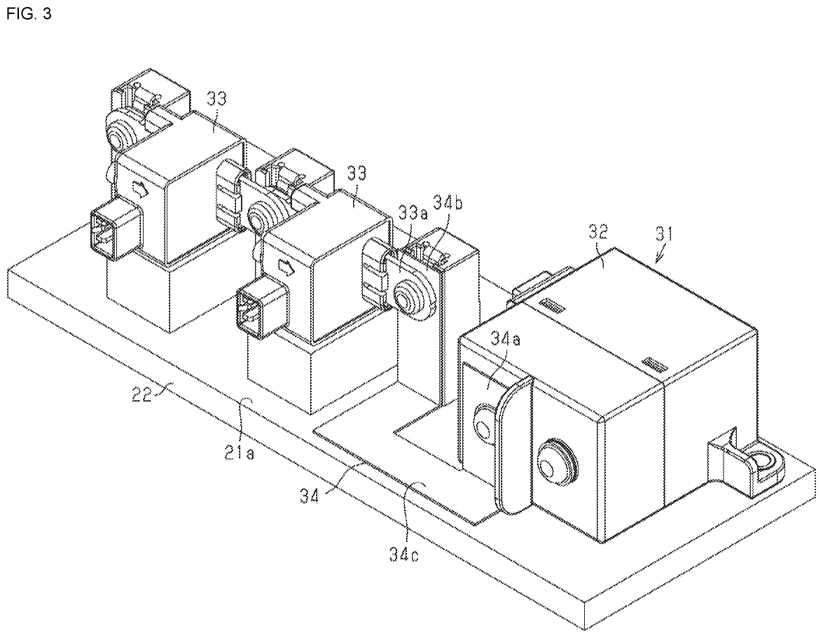

As shown in FIGS. 2 and 3, the electric circuit components 31 include a contactor 32 serving as a magnetic field generating component that generates a magnetic field, electric current sensors 33, and a bus bar 34. Note that the figures of the present embodiment illustrate only one contactor 32, two electric current sensors 33, and one bus bar 34, and other electric circuit components 31 are not illustrated. That is, the electric circuit components 31 of the electrical junction box 11 may include a plurality of contactors 32 and a plurality bus bars 34, and may also include other electric circuit components 31 such as a flexible coated electric wire and a fuse, for example. In addition, although current sensors each having a Hall element are adopted as the electric current sensors 33 according to the present embodiment, there is no limitation thereto, and through-type current sensors may also be adopted.

In the present embodiment, the contactor 32 and the two electric current sensors 33 are arranged along a side of the lower case 22, specifically, a long side. The contactor 32 is connected, via the bus bar 34, to a connection terminal 33a of one of the two electric current sensors 33 connected in series.

As shown in FIG. 3, the bus bar 34 is disposed such that the main surface of the bus bar 34 faces the bottom surface 21a inside the case 21. Specifically, the bus bar 34 includes a first connection end portion 34a, a second connection end portion 34b, and a coupling portion 34c that links the first connection end portion 34a and the second connection end portion 34b to each other. The main surface of the coupling portion 34c is disposed so as to face the bottom surface 21a inside the case 21. The first connection end portion 34a is raised upright from the coupling portion 34c such that the main surface of the bus bar 34 is orthogonal to the bottom surface 21a, and is connected to the contactor 32. In addition, the second connection end portion 34b is raised upright from the coupling portion 34c such that the main surface of the bus bar 34 is orthogonal to the bottom surface 21a, and is connected to the connection terminal 33a of the electric current sensor 33.

### Configuration of Metal Plate 41

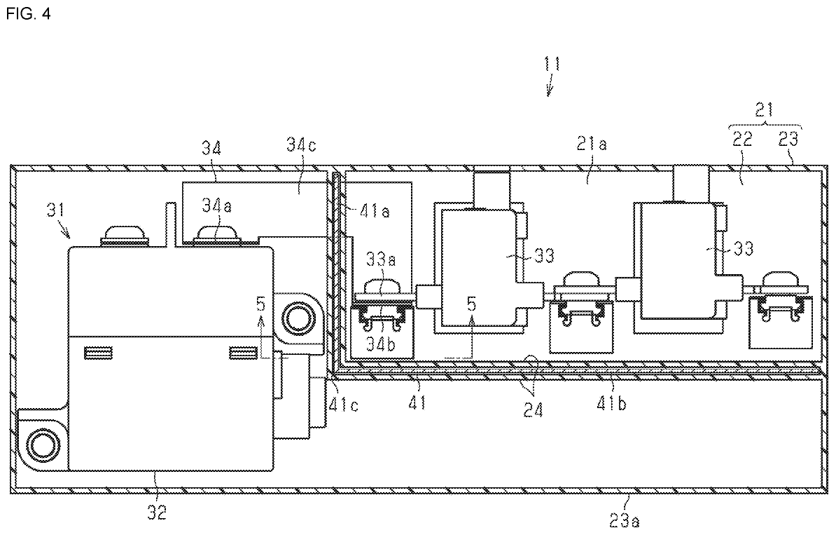

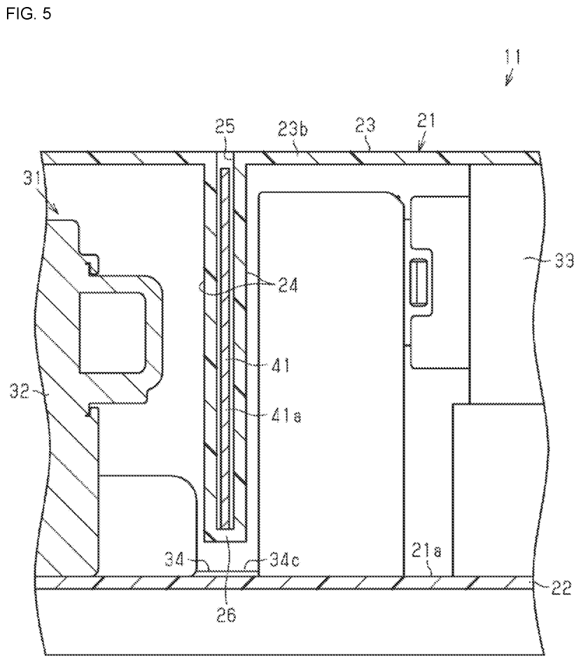

As shown in FIGS. 4 and 5, the metal plate 41 is interposed between the contactor 32 and the electric current sensors 33. In other words, the metal plate 41 is provided to partition the contactor 32 and the electric current sensors 33.

The case 21 includes cover portions 24 that cover main surfaces of the metal plate 41 inside the case 21. The cover portions 24 according to the present embodiment are provided in the upper case 23. The cover portions 24 are formed to cover the entire main surfaces of the metal plate 41.

Specifically, as shown in FIG. 4, first, the metal plate 41 includes two different flat surface portions disposed around the electric current sensors 33, namely a first flat surface portion 41a and a second flat surface portion 41b. In addition, the metal plate 41 includes a bent portion 41c that connects the first flat surface portion 41a and the second flat surface portion 41b. That is, the metal plate 41 is formed as a single bent component. The first flat surface portion 41a and the second flat surface portion 41b extend from the bent portion 41c in directions orthogonal to each other. The metal plate 41 is disposed such that the first flat surface portion 41a is parallel to the short sides of the lower case 22, and the second flat surface portion 41b is parallel to the long sides of the lower case 22. The metal plate 41 surrounds the electric current sensors 33 in cooperation with edge portions of the lower case 22. The metal plate 41 is disposed in such a manner as to shield all of the surfaces of the electric current sensors 33 that face the contactor 32 and the surface of the contactor 32 that faces the electric current sensors 33.

In addition, as shown in FIGS. 4 and 5, the first flat surface portion 41a, which is a portion of the metal plate 41, extends above the coupling portion 34c of the bus bar 34. The first flat surface portion 41a is disposed in such a manner as to cross the coupling portion 34c extending along the long side of the lower case 22 as viewed from above.

In addition, as shown in FIG. 5, the upper case 23 includes an insertion opening 25 through which the metal plate 41 can be inserted between the cover portions 24 from the outside, and an accommodating bottom portion 26 that links the cover portions 24 to each other at a leading end portion in the insertion direction of the metal plate 41. The insertion opening 25 according to the present embodiment is provided in the upper wall portion 23b of the upper case 23, and is open upward. Note that, in the present embodiment, the metal plate 41 is fixed by being press-fitted from the insertion opening 25 between the cover portions 24. For example, a plurality of press-fit protrusions (not shown) are provided on the surfaces of the cover portions 24 that face each other, and the metal plate 41 is held by being clamped by these press-fit protrusions.

Next, the operation of the electrical junction box 11 configured as described above will be described.

The electric circuit components 31 of the electrical junction box 11 are electrically connected to the battery cells housed in the battery pack case together with the electrical junction box 11. By the electric circuit components 31 of the electrical junction box 11 monitoring current values, the temperatures, and the like of the battery cells, optimum input/output of the battery pack is realized.

Next, the effect of the above embodiment will be described below.

Since the metal plate 41 interposed between the contactor 32 and the electric current sensors 33 is provided, the electric current sensors 33 can be kept from being affected by a magnetic field generated by the contactor 32. Thus, it is possible to suppress a decrease in the detection accuracy of the electric current sensors 33. Accordingly, for example, there is no need to dispose the contactor 32 and the electric current sensors 33 with a large distance therebetween, and thus it is easy to decrease the size of the electrical junction box 11. In addition, since the case 21 includes the cover portions 24 that cover the main surfaces of the metal plate 41 inside the case 21, the metal plate 41 is prevented from coming into direct contact with other electric circuit components 31. Thus, for example, it is possible to prevent the bus bar 34 that connects the contactor 32 and the electric current sensors 33 from being electrically connected to the metal plate 41. In addition, for example, even when the electrical junction box 11 vibrates while the vehicle is travelling, a flexible coated electric wire (not shown) is prevented from being damaged by rubbing against an edge or the like of the metal plate 41.

The case 21 includes the insertion opening 25 through which the metal plate 41 can be inserted between the cover portions 24 from the outside, and the accommodating bottom portion 26 that links the cover portions 24 to each other at a leading end portion in the insertion direction of the metal plate 41. Thus, by inserting the metal plate 41 from the insertion opening 25, the metal plate 41 can be easily disposed.

The bus bar 34 that connects the contactor 32 and the electric current sensors 33 is disposed such that the main surface of the bus bar 34 faces the bottom surface 21a inside the case 21, and thus the metal plate 41 can be easily interposed between the contactor 32 and the electric current sensors 33. That is, for example, in a configuration in which the bus bar is disposed such that the main surface of the bus bar 34 is orthogonal to the bottom surface 21a, it is difficult to interpose the metal plate 41 between the contactor 32 and the electric current sensors 33 due to interference of the bus bar, but that can be avoided.

The metal plate 41 includes two different flat surface portions disposed around the electric current sensors 33, namely the first flat surface portion 41a and the second flat surface portion 41b. Thus, for example, it is possible to orderly partition the contactor 32 and the electric current sensors 33 compared with a case where a metal plate consisting of a single flat surface portion is used.

The metal plate 41 includes the bent portion 41c that links the first flat surface portion 41a and the second flat surface portion 41b, and thus, for example, in contrast to a case where the first flat surface portion 41a and the second flat surface portion 41b are independent separate members, the number of components can be reduced.

The metal plate 41 is disposed in such a manner as to shield all of the surfaces of the electric current sensors 33 that face the contactor 32 and the surface of the contactor 32 that faces the electric current sensors 33. Thus, for example, compared with a configuration where some of the surfaces are not shielded, the electric current sensors 33 can be further kept from being affected by a magnetic field generated by the contactor 32. Thus, it is possible to further suppress a decrease in the detection accuracy of the electric current sensors 33.

The present embodiment can be modified and implemented as follows. The present embodiment and the following modified examples can be combined unless they are technically inconsistent.

In the above embodiment, the case 21 includes the insertion opening 25 through which the metal plate 41 can be inserted between the cover portions 24 from the outside, and the accommodating bottom portion 26 that links the cover portions 24 to each other at a leading end portion in the insertion direction of the metal plate 41, but there is no limitation thereto. For example, by insert molding the metal plate 41 at the time of molding of the upper case 23, the metal plate 41 may be provided so as to be covered with the cover portions of the upper case 23.

In the above embodiment, the insertion opening 25 is provided in the upper wall portion 23b of the upper case 23, and is open upward, but there is no limitation thereto, and, for example, the insertion opening 25 may be provided in the side wall portion 23a and be open laterally. In addition, the cover portions 24, the insertion opening 25, and the accommodating bottom portion 26 may be provided on the lower case 22, and the insertion opening 25 may be open downward.

In the above embodiment, the bus bar 34 that connects the contactor 32 and the electric current sensors 33 is disposed such that the main surface of the bus bar 34 faces the bottom surface 21a inside the case 21, but there is no limitation thereto, and the bus bar 34 may be disposed such that the main surface of the bus bar 34 is orthogonal to the bottom surface 21a.

In the above embodiment, the metal plate 41 includes two different flat surface portions disposed around the electric current sensors 33, namely the first flat surface portion 41a and the second flat surface portion 41b, but there is no limitation thereto, and, for example, the metal plate 41 may include three or more different flat surface portions. In addition, for example, the metal plate may include one flat surface portion.

In the above embodiment, the metal plate 41 includes the bent portion 41c that links the first flat surface portion 41a and the second flat surface portion 41b, but there is no limitation thereto, and, for example, a configuration may be adopted in which the first flat surface portion 41a and the second flat surface portion 41b are independent separate members.

In the above embodiment, the metal plate 41 is disposed in such a manner as to shield all of the surfaces of the electric current sensors 33 that face the contactor 32 and the surface of the contactor 32 that faces the electric current sensors 33, but there is no limitation thereto, and a configuration may be adopted in which only some of the surfaces are shielded.

In the above embodiment, the electric circuit components 31 include the contactor 32 serving as a magnetic field generating component, but there is no limitation thereto, and a configuration may be adopted in which another magnetic-field generating component such as a core that generates a magnetic field is included. Note that, as a matter of course, in this case, the metal plate 41 is interposed between the other magnetic field generating component such as a core and the electric current sensors 33.

In the above embodiment, the metal plate 41 is fixed by being press-fitted between the cover portions 24 from the insertion opening 25, but there is no limitation thereto, and the metal plate 41 may be configured to be prevented from coming off by being retained by claws or the like in a state of being inserted between the cover portions 24 from the insertion opening 25.

In the above embodiment, the electrical junction box 11 is provided in a battery pack mounted in a vehicle such as an electric automobile, but there is no limitation thereto, and the electrical junction box 11 may be provided in another apparatus.

The illustrated contactor 32 according to the non-limiting embodiment is an example of an electromagnetic coil-type magnetic noise source or a non sensor magnetic noise source. As shown in FIGS. 4 and 5, the cover portions 24 and the accommodating bottom portion 26 may be referred to as a partition configured to divide the internal space of the case 21 into a magnetic noise source compartment for accommodating an electromagnetic coil-type magnetic noise source that may be the contactor 32 (for example, the space on the left side in FIG. 5) and an electric current sensor compartment for accommodating the electric current sensors 33 (for example, the space on the right side in FIG. 5). As shown in FIG. 5, this partition may extend linearly from the upper surface of the upper case 23 toward the lower surface of the lower case 22, and may have a hollow double-wall structure, for example.

The illustrated metal plate 41 according to the non-limiting embodiment is an example of a magnetic noise shielding plate having an outermost edge, a plate thickness, a plate width, and a plate length, and optionally having a bent corner portion or an alignment corner portion. As shown in FIGS. 1, 4, and 5, the insertion opening 25, the cover portions 24, and the accommodating bottom portion 26 of the case 21 constitute an example of a slot-like holder. The slot-like holder may be configured to accommodate the entire metal plate 41 such that the outermost edge of the metal plate 41 does not protrude from the contour or the outermost surface of the case 21, and such that the surface of the metal plate 41 is not exposed to the internal space of the case 21. The slot-like holder may have a slot width that matches or corresponds to the plate thickness of the metal plate 41, a slot depth that matches or corresponds to the plate width of the metal plate 41, and a slot length that matches or corresponds to the plate length of the metal plate 41. When the metal plate 41 has a bent corner portion or an alignment corner portion, the slot-like holder may have a bent space corresponding to the bent corner portion or the alignment corner portion of the metal plate 41. In the example shown in FIG. 5, the insertion opening 25 of the outer surface of the case 21 is configured to enable insertion from the outside of the case 21 into the slot-like holder, and may be referred to as a slot-like entrance. Optionally, the insertion opening 25 of the case 21 may be configured to enable removal of the metal plate 41 from the slot-like holder to the outside of the case 21.

1. An electrical junction box comprising:
a case made of a resin material; electric circuit components configured to be accommodated and held in the case, the electric circuit components including an electric current sensor and a magnetic-field generating component configured to generate a magnetic field; and a metal plate interposed between the magnetic-field generating component and the electric current sensor,
wherein the case includes cover portions covering main surfaces of the metal plate inside the case.

2. The electrical junction box according to claim 1,
wherein the case includes: an insertion opening through which the metal plate is insertable between the cover portions from the outside; and an accommodating bottom portion that links the cover portions to each other at a leading end portion in an insertion direction of the metal plate.

3. The electrical junction box according to claim 1,
wherein the electric circuit components include a bus bar that connects the magnetic-field generating component and the electric current sensor, and
the bus bar is disposed such that a main surface of the bus bar faces a bottom surface inside the case.

4. The electrical junction box according to claim 1,
wherein the metal plate includes a plurality of different flat surface portions disposed around the electric current sensor or the magnetic-field generating component.

5. The electrical junction box according to claim 4,
wherein the metal plate includes a bent portion that links the plurality of different flat surface portions.

6. The electrical junction box according to claim 1,
wherein the metal plate is disposed in such a manner as to shield all of a surface of the electric current sensor that faces the magnetic-field generating component and a surface of the magnetic-field generating component that faces the electric current sensor.
